(19) United States
(12) Patent Application Publication
(10) Pub. No.: US 2014/0116508 A1
(43) Pub. Date: May 1, 2014

(54) COLUMN STRUCTURE THIN FILM MATERIAL USING METAL OXIDE BEARING SEMICONDUCTOR MATERIAL FOR SOLAR CELL DEVICES

(71) Applicant: Stion Corporation, San Jose, CA (US)

(72) Inventor: Howard W.H. Lee, Saratoga, CA (US)

(73) Assignee: Stion Corporation, San Jose, CA (US)

(21) Appl. No.: 14/150,585

(22) Filed: Jan. 8, 2014

Related U.S. Application Data
(62) Division of application No. 13/183,268, filed on Jul. 14, 2011, now abandoned.
Application No. 13/183,268 is a division of application No. 12/237,371, filed on Sep. 24, 2008, now abandoned.
(60) Provisional application No. 60/976,392, filed on Sep. 28, 2007.

(51) Int. Cl. H01L 31/0248

(52) U.S. Cl. CPC H01L 31/0248
USPC 136/256; 136/252

(57) ABSTRACT

A thin film material structure for solar cell devices. The thin film material structure includes a thickness of material comprises a plurality of single crystal structures. In a specific embodiment, each of the single crystal structure is configured in a column like shape. The column like shape has a dimension of about 0.01 micron to about 10 microns characterizes a first end and a second end. An optical absorption coefficient of greater than 10⁴ cm⁻¹ for light in a wavelength range comprising about 400 cm⁻¹ to about 700 cm⁻¹ characterizes the thickness of material.

### CROSS-REFERENCES TO RELATED APPLICATIONS

This application is a divisional of U.S. patent application Ser. No. 13/183,268 filed on Jul. 14, 2011, which is a divisional of U.S. patent application Ser. No. 12/237,371 filed on Sep. 24, 2008, which claims priority to U.S. Provisional Patent Application No. 60/976,392 filed on Sep. 28, 2007 the disclosures of which are incorporated by reference herein in their entirety for all purposes.

### BACKGROUND OF THE INVENTION

The present invention relates generally to photovoltaic materials. More particularly, the present invention provides a method and structure for manufacture of photovoltaic materials using a thin film process including metal oxide bearing materials such as copper oxide and the like. Merely by way of example, the present method and structure have been implemented using a nanostructure configuration, but it would be recognized that the other configurations such as bulk materials may be used.

From the beginning of time, human beings have been challenged to find way of harnessing energy. Energy comes in the forms such as petrochemical, hydroelectric, nuclear, wind, biomass, solar, and more primitive forms such as wood and coal. Over the past century, modern civilization has relied upon petrochemical energy as an important source of energy. Petrochemical energy includes gas and oil. Gas includes lighter forms such as butane and propane, commonly used to heat homes and serve as fuel for cooking Gas also includes gasoline, diesel, and jet fuel, commonly used for transportation purposes. Heavier forms of petrochemicals can also be used to heat homes in some places. Unfortunately, petrochemical energy is limited and essentially fixed based upon the amount available on the planet Earth. Additionally, as more human beings begin to drive and use petrochemicals, it is becoming a rather scarce resource, which will eventually run out over time.

More recently, clean sources of energy have been desired. An example of a clean source of energy is hydroelectric power. Hydroelectric power is derived from electric generators driven by the force of water that has been held back by large dams such as the Hoover Dam in Nevada. The electric power generated is used to power up a large portion of Los Angeles, Calif. Other types of clean energy include solar energy. Specific details of solar energy can be found throughout the present background and more particularly below.

Solar energy generally converts electromagnetic radiation from our sun to other useful forms of energy. These other forms of energy include thermal energy and electrical power. For electrical power applications, solar cells are often used. Although solar energy is clean and has been successful to a point, there are still many limitations before it becomes widely used throughout the world. As an example, one type of solar cell uses crystalline materials, which form from semiconductor material ingots. These crystalline materials include photo-diode devices that convert electromagnetic radiation into electrical current. Crystalline materials are often costly and difficult to make on a wide scale. Additionally, devices made from such crystalline materials have low energy conversion efficiencies. Other types of solar cells use “thin film” technology to form a thin film of photosensitive material to be used to convert electromagnetic radiation into electrical current. Similar limitations exist with the use of thin film technology in making solar cells. That is, efficiencies are often poor. Additionally, film reliability is often poor and cannot be used for extensive periods of time in conventional environmental applications. These and other limitations of these conventional technologies can be found throughout the present specification and more particularly below.

From the above, it is seen that improved techniques for manufacturing photovoltaic materials and resulting devices are desired.

### BRIEF SUMMARY OF THE INVENTION

According to embodiments of the present invention, techniques directed to fabrication of photovoltaic cell is provided. More particularly, embodiments according to the present invention provide a method and a structure for a thin film semiconductor material using a metal oxide bearing species. But it would be recognize that embodiments according to the present invention have a much broader range of applicability.

In a specific embodiment, a thin film material structure for solar cell devices is provided. The thin film material structure includes a thickness of material. The thickness of material includes a plurality of single crystal structures. In a specific embodiment, each of the single crystal structure is configured in a column liked shape. Each of the column liked shape has a first end and a second end, and a lateral region connecting the first end and the second end.

In a specific embodiment, the first end and the second end has a dimension ranging from about 0.01 micron to about 10 microns, but can be others. An optical absorption coefficient of greater than 10⁴ cm⁻¹ for light in a wavelength range comprising about 400 cm⁻¹ to about 700 cm⁻¹ characterizes the thickness of material.

In a specific embodiment, a method for forming thin film material structure for solar cell devices is provided. The method includes providing a substrate having a surface region. The method forms a first electrode structure overlying the surface region. In a specific embodiment, the method includes forming a thickness of material overlying the first electrode structure. The thickness of material includes a plurality of single crystal structures. Each of the single crystal structure is configured in a column like shape in a preferred embodiment. The column like shape has a first end and a second end each having a dimension of ranging from about 0.01 micron to about 10 microns but can be others. The thickness of material is characterized by an optical absorption of greater than 10⁴ cm⁻¹ for light in a wavelength range comprising about 400 cm⁻¹ to about 700 cm⁻¹.

Depending upon the embodiment, the present invention provides an easy to use process that relies upon conventional technology that can be nanotechnology based. Such nanotechnology based materials and process lead to higher conversion efficiencies and improved processing according to a specific embodiment. In some embodiments, the method may provide higher efficiencies in converting sunlight into electrical power. Depending upon the embodiment, the efficiency can be about 10 percent or 20 percent or greater for the resulting solar cell according to the present invention. Additionally, the method provides a process that is compatible with conventional process technology without substantial modifications to conventional equipment and processes. In a specific embodiment, the present method and structure can also be provided using large scale manufacturing techniques, which reduce costs associated with the manufacture of the photovoltaic devices. In another specific embodiment, the present method and structure can also be provided using solution based processing. In a specific embodiment, the present method uses processes and provides material that are safe to the environment. Depending upon the embodiment, one or more of these benefits may be achieved. These and other benefits will be described in more throughout the present specification and more particularly below.

Various additional objects, features and advantages of the present invention can be more fully appreciated with reference to the detailed description and accompanying drawings that follow.

### BRIEF DESCRIPTION OF THE DRAWINGS

FIG. 1 is a simplified diagram illustrating a solar cell device according to embodiments of the present invention.

FIG. 2-3 are simplified diagrams illustrating a structure for a thin film metal oxide semiconductor material for the solar cell device according to an embodiments of the present invention.

FIG. 4-9 are simplified diagrams illustrating a method for fabricating the solar cell device using the thin film metal oxide semiconductor material according to an embodiment of the present invention.

### DETAILED DESCRIPTION OF THE INVENTION

According to embodiments of the present invention, techniques for forming a thin film metal oxide semiconductor material are provided. More particularly, embodiments according to the present invention provide a method and structures for thin film metal oxide semiconductor material for solar cell application. But it would be recognized that embodiments according to the present invention have a much broader range of applicability.

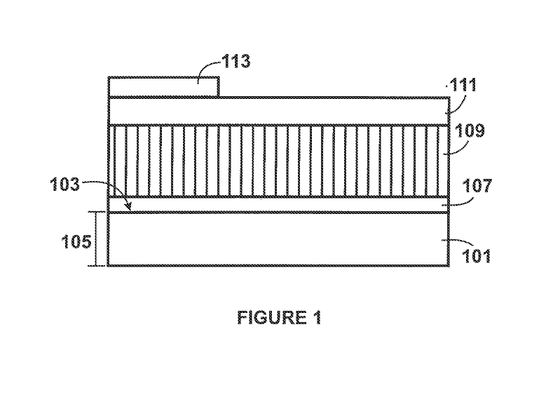

FIG. 1 is a simplified diagram illustrating a solar cell device structure using a thin metal oxide semiconductor film structure for solar cell application according to an embodiment of the present invention. The diagram is merely an illustration and should not unduly limit the claims herein. One skilled in the art would recognize other modifications, variations, and alternatives. As shown in FIG. 1, a substrate 101 is provided. The substrate includes a surface region 103 and a thickness 105. The substrate can be a semiconductor such as silicon, silicon germanium, germanium, a combination of these, and the like. The substrate can also be a metal or metal alloy such as nickel, stainless steel, aluminum, and the like. Alternatively, the substrate can be a transparent material such as glass, quartz, or a polymeric material. The substrate may also be a multilayer structured material or a graded material. Of course there can be other variations, modifications, and alternatives.

As shown in FIG. 1, a first electrode structure 107 is provided overlying the surface region of the substrate. In a specific embodiment, the first electrode structure can be made of a suitable material or a combination of materials. The first electrode structure can be made from a transparent conductive electrode or materials that are light reflecting or light blocking depending on the embodiment. Examples of the optically transparent material can include indium tin oxide (ITO), aluminum doped zinc oxide, fluorine doped tin oxide and others. In a specific embodiment, the first electrode may be made from a metal material. The metal material can include gold, silver, nickel, platinum, aluminum, tungsten, molybdenum, a combination of these, or an alloy, among others. In a specific embodiment, the metal material may be deposited using techniques such as sputtering, electroplating, electrochemical deposition and others. Alternatively, the first electrode structure may be made of a carbon based material such as carbon or graphite. Yet alternatively, the first electrode structure may be made of a conductive polymer material, depending on the application. Of course there can be other variations, modifications, and alternatives.

In a specific embodiment, a thin film metal oxide semiconductor material 109 is allowed to form overlying the first electrode structure. As shown, the thin film metal oxide semiconductor material is substantially in physical and electrical contact with the first electrode structure. Further details of the thin film metal oxide semiconductor material are provided throughout the present specification and particularly below.

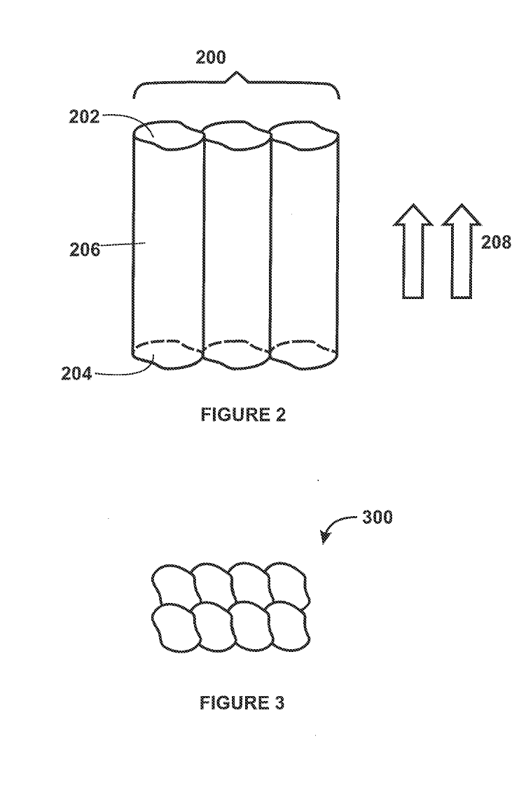

Referring to FIG. 2, the thin film metal oxide semiconductor material comprises a plurality of single crystal structures 200 according to a specific embodiment. Each of the plurality of single crystal structure can have a certain spatial configuration. In a specific embodiment, each of the plurality of single crystal structure is configured in a column like shape. As shown, the column like shape includes a first end 202 and a second end 204. A lateral region 206 connects the first end and the second end. The first end and the second end are irregularly shaped and substantially circular. In a specific embodiment, each of the single crystal structures are provided in a closely packed configuration. That is, each of the plurality of the single crystal structures are arranged substantially parallel to each other in a lateral direction 208, as shown in

FIG. 2. A top view 300 of the thin film metal oxide semiconductor material is shown in FIG. 3. Of course there can be other variations, modifications, and alternatives.

In a specific embodiment, each of the plurality of single crystal structures can have a spatial characteristic, that is each of the single crystal structures can be nano based in a specific embodiment. In a specific embodiment, each of the single crystal structures is characterized by a diameter ranging from about 0.01 micron to about 10 microns but can be others. Of course there can be other variations, modifications, and alternatives.

In a specific embodiment, the thin film metal oxide semiconductor material can be oxides of copper, for example, cupric oxide or cuprous oxide. In an alternative embodiment, the thin film metal oxide semiconductor material can be made of oxides of iron such as ferrous oxide FeO, ferric oxide Fe₂O₃, and the like. Of course there can be other variations, modifications, and alternatives.

Taking copper oxide as the thin film metal oxide semiconductor material as an example, copper oxide may be deposited using a suitable techniques or a combination of techniques. The suitable technique can include sputtering, electrochemical deposition, electropheritic reaction, a combination, and others. In a specific embodiment, the copper oxide can be deposited by an electrochemical deposition method using copper sulfate, or copper chloride, and the like, as a precursor. Of course there can be other variations, modifications, and alternatives.

In a specific embodiment, the thin film metal oxide semiconductor material is characterized by a first band gap. The first band gap can range from about 1.0 eV to about 2.0 eV and preferably range from about 1.2 eV to about 1.8 eV. Of course there can be other variations, modifications, and alternatives.

In a specific embodiment, the column like shape of each of the plurality of single crystal structures provides for a grain boundary region for each of the single crystal structures. Such grain boundary region allows for a diode device structure within each of the plurality of single crystal structures for the thin film oxide semiconductor material according to a specific embodiment. Of course there can be other variations, modifications, and alternatives.

In a specific embodiment, the thin film metal oxide semiconductor material is characterized by an optical absorption coefficient. The optical absorption coefficient is at least 10⁴ cm⁻¹ for light in a wavelength range comprising about 400 nm to about 800 nm. In an alternative embodiment, the thin film metal oxide semiconductor material can have an optical absorption coefficient of at least 10⁴ cm⁻¹ for light in a wavelength range comprising about 450 cm⁻¹ to about 750 cm⁻¹. Of course there can be other variations, modifications, and alternatives.

Referring back to FIG. 1, the solar cell device structure includes a semiconductor material 113 overlying the thin film metal oxide semiconductor material. In a specific embodiment, the semiconductor material has an impurity characteristic opposite to that of the thin film metal oxide semiconductor material. As merely an example, the thin film metal oxide semiconductor material can have a p type impurity characteristics, the semiconductor material can have a n type impurity characteristics. In a specific embodiment, the thin film metal oxide semiconductor material can have a p⁻ type impurity characteristics, the semiconductor material has a n⁺ type impurity characteristics. Additionally, the semiconductor material is characterized by a second bandgap. In a specific embodiment, the second bandgap is greater than the first bandgap. Of course one skilled in the art would recognize other variations, modifications, and alternatives.

Again referring to FIG. 1, a high resistivity buffer layer 111 is provided overlying the semiconductor material. As shown in FIG. 1, a second electrode structure 113 is provided overlying a surface region of the buffer layer. In a specific embodiment, the second electrode structure can be made of a suitable material or a combination of materials. The second electrode structure can be made from a transparent conductive electrode or materials that are light reflecting or light blocking depending on the embodiment. Examples of the optically transparent material can include indium tin oxide (ITO), aluminum doped zinc oxide, fluorine doped tin oxide and others. In a specific embodiment, the second electrode may be made from a metal material. The metal material can include gold, silver, nickel, platinum, aluminum, tungsten, molybdenum, a combination of these, or an alloy, among others. In a specific embodiment, the metal material may be deposited using techniques such as sputtering, electroplating, electrochemical deposition and others. Alternatively, the second electrode structure may be made of a carbon based material such as carbon or graphite. Yet alternatively, the second electrode structure may be made of a conductive polymer material, depending on the application. Of course there can be other variations, modifications, and alternatives.

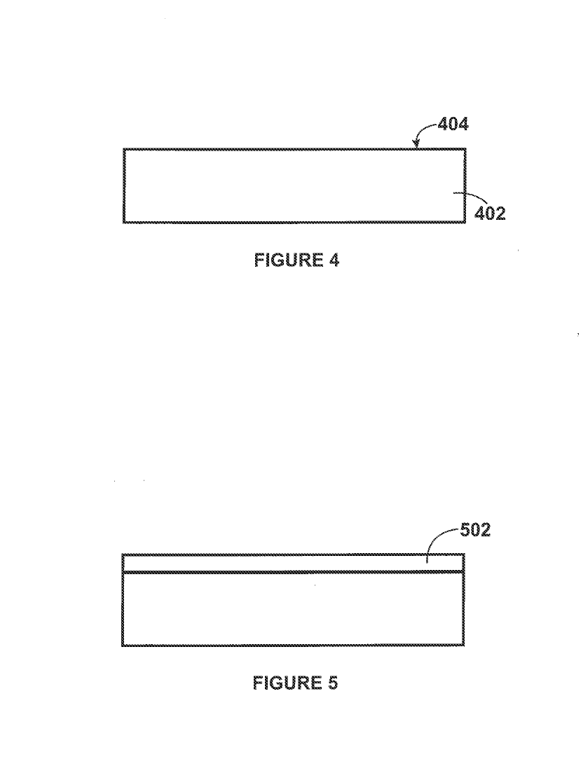

FIG. 4-9 are simplified diagrams illustrating a method of fabricating a solar cell device using a thin film metal oxide semiconductor material according to an embodiment of the present invention. These diagrams are merely examples and should not unduly limit the claims herein. One skilled in the art would recognize other variations, modifications, and alternatives. As shown in FIG. 4, a substrate member 402 including a surface region 404 is provided. The substrate member can be made of an insulator material, a conductor material, or a semiconductor material, depending on the application. In a specific embodiment, the conductor material can be nickel, molybdenum, aluminum, or a metal alloy such as stainless steel and the likes. In a embodiment, the semiconductor material may include silicon, germanium, silicon germanium, compound semiconductor material such as III-V materials, II-VI materials, and others. In a specific embodiment, the insulator material can be a transparent material such as glass, quartz, fused silica. Alternatively, the insulator material can be a polymer material, a ceramic material, or a layer or a composite material depending on the application. The polymer material may include acrylic material , polycarbonate material, and others, depending on the embodiment.

Referring to FIG. 5, the method includes forming a first conductor structure 502 overlying the surface region of the substrate member. In a specific embodiment, the first electrode structure can be made of a suitable material or a combination of materials. The first electrode structure can be made from a transparent conductive electrode or materials that are light reflecting or light blocking depending on the embodiment. Examples of the optically transparent conductive material can include indium tin oxide (ITO), aluminum doped zinc oxide, fluorine doped tin oxide and others. The transparent conductive material may be deposited using techniques such as sputtering, or chemical vapor deposition. In a specific embodiment, the first electrode may be made from a metal material. The metal material can include gold, silver, nickel, platinum, aluminum, tungsten, molybdenum, a combination of these, or an alloy, among others. In a specific embodiment, the metal material may be deposited using techniques such as sputtering, electroplating, electrochemical deposition and others. Alternatively, the first electrode structure may be made of a carbon based material such as carbon or graphite. Yet alternatively, the first electrode structure may be made of a conductive polymer material, depending on the application. Of course there can be other variations, modifications, and alternatives.

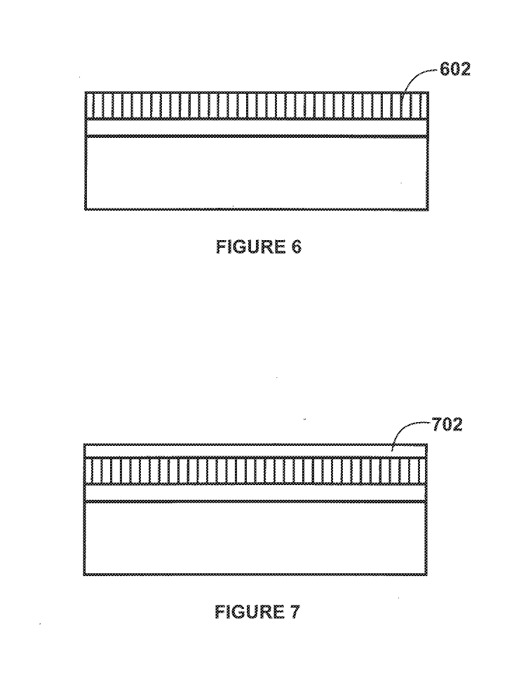

Referring to FIG. 6, the method includes forming a thin film metal oxide semiconductor material 602 overlying the first electrode structure. The thin film metal oxide semiconductor material has a P⁻ type impurity characteristics in a specific embodiment.

Preferably, the thin film metal oxide semiconductor material is characterized by an optical absorption coefficient greater than about 10⁴ cm⁻¹in the wavelength ranging from about 400 nm to about 750 nm in a specific embodiment. In a specific embodiment, the thin film metal oxide semiconductor material has a bandgap ranging from about 1.0 eV to about 2.0 eV. As merely an example, the thin film metal oxide semiconductor material can be oxides of copper (that is cupric oxide or cuprous oxide, or a combination) deposited by an electrochemical method or by chemical vapor deposition technique. Of course there can be other variations, modifications, and alternatives.

In a specific embodiment, the method includes forming a semiconductor material 702 having a N⁺ impurity characteristics 602 overlying the absorber layer as shown in FIG. 7. The semiconductor material can comprise a second metal oxide semiconductor material in a specific embodiment. Alternatively, the N⁺ layer can comprise a metal sulfide material. Examples of the semiconductor material can include one or more oxides of copper, zinc oxide, and the like. Examples of metal sulfide material can include zinc sulfide, iron sulfides and others. The semiconductor material may be provided in various spatial morphologies of different shapes and sizes. In a specific embodiment, the semiconductor material may comprise of suitable materials that are nanostructured, such as nanocolumn, nanotubes, nanorods, nanocrystals, and others. In an alternative embodiment, the semiconductor material may also be provided as other morphologies, such as bulk materials depending on the application. Of course there can be other variations, modifications, and alternatives. Of course there can be other modifications, variations, and alternatives.

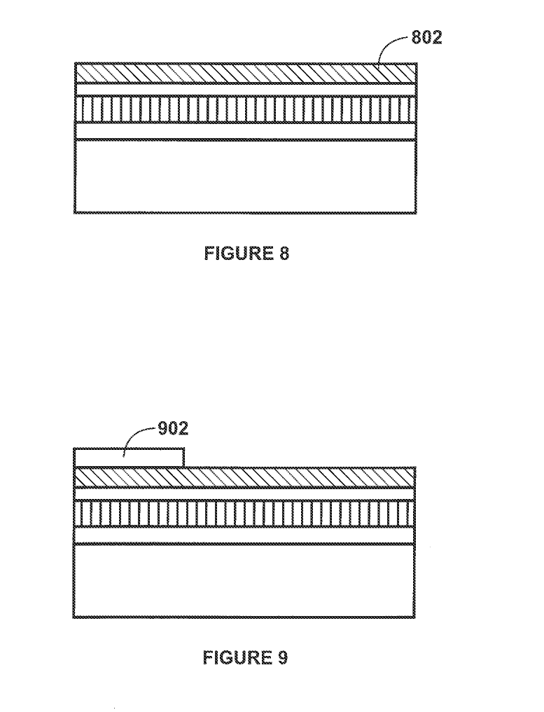

Referring to FIG. 8, the method for fabricating a solar cell device using thin metal oxide semiconductor material includes providing a buffer layer 801 overlying a surface region of the semiconductor material. In a specific embodiment, the buffer layer comprises of a suitable high resistivity material. Of course there can be other modifications, variations, and alternatives.

As shown in FIG. 9, the method includes forming a second conductor layer to form a second electrode structure 902 overlying the buffer layer. In a specific embodiment, the second electrode structure can be made of a suitable material or a combination of materials. The second electrode structure can be made from a transparent conductive electrode or materials that are light reflecting or light blocking depending on the embodiment. Examples of the optically transparent conductive material can include indium tin oxide (ITO), aluminum doped zinc oxide, fluorine doped tin oxide and others. The transparent conductive material may be deposited using techniques such as sputtering, or chemical vapor deposition. In a specific embodiment, the first electrode may be made from a metal material. The metal material can include gold, silver, nickel, platinum, aluminum, tungsten, molybdenum, a combination of these, or an alloy, among others. In a specific embodiment, the metal material may be deposited using techniques such as sputtering, electroplating, electrochemical deposition and others. Alternatively, the second electrode structure may be made of a carbon based material such as carbon or graphite. Yet alternatively, the second electrode structure may be made of a conductive polymer material, depending on the application. Of course there can be other variations, modifications, and alternatives.

It is also understood that the examples and embodiments described herein are for illustrative purposes only and that various modifications or changes in light thereof will be suggested to persons skilled in the art and are to be included within the spirit and purview of this application and scope of the appended claims.

What is claimed is:

1. A solar cell device structure for a solar cell, the solar cell device structure comprises:
a substrate member having a surface region;
a first electrode structure overlying the surface region of the substrate member;
a layer of material having a P⁻ type impurity characteristics overlying the first electrode structure, the layer of material comprising a plurality of single crystal structures, each of the single crystal structure being configured in a column like shape having a dimension of about 0.01 micron to about 10 micron and being characterized by a first end and a second end, wherein the layer of material is characterized by an optical absorption coefficient of greater than 10⁴ cm⁻¹ for light in a wavelength range comprising about 400 nm to about 750 nm;
a semiconductor material having a N⁺ type impurity characteristics overlying the layer of material;
a resistive buffer layer overlying the semiconductor material; and
a second electrode structure overlying the buffer layer.

2. The solar cell device structure of claim 1 wherein the substrate member comprises a semiconductor material or a compound semiconductor material.

3. The solar cell device structure of claim 1 wherein the substrate member is transparent.

4. The solar cell device structure of claim 1 wherein the substrate member comprises a metal including nickel, aluminum, or stainless steel.

5. The solar cell device structure of claim 1 wherein the substrate member comprises an organic material including polycarbonate or acrylic material.

6. The solar cell device structure of claim 1 wherein the first electrode structure comprises a transparent conductive material including indium tin oxide, fluorine doped tin oxide, or aluminum doped zinc oxide.

7. The solar cell device structure of claim 1 wherein the first electrode comprises a metal material including gold, silver, platinum, nickel, aluminum, or a composite material such as metal alloys.

8. The solar cell device structure of claim 1 wherein the first electrode comprises an organic material including a conductive polymer material.

9. The solar cell device structure of claim 1 wherein the first electrode comprises a carbon based material.

10. The solar cell device structure of claim 1 wherein the second electrode comprises a transparent conductive material selected from a group comprising indium tin oxide, fluorine doped tin oxide, or aluminum doped zinc oxide.

11. The solar cell device structure of claim 1 wherein the second electrode comprises a metal material including gold, silver, platinum, nickel, aluminum, or a composite material.

12. The solar cell device structure of claim 1 wherein the second electrode comprises an organic material.

13. The solar cell device structure of claim 1 wherein the second electrode comprises graphite.

14. The solar cell device structure of claim 1 wherein the layer of material has a first band gap ranging from about 0.8 eV to about 1.3 eV.

15. The solar cell device structure of claim 1 wherein the layer of material comprises a metal oxide material.

16. The solar cell device structure of claim 1 wherein the layer of material comprises a metal sulfide material.

17. The solar cell device structure of claim 1 wherein the semiconductor material has a N⁺ impurity characteristics.

18. The solar cell device structure of claim 1 wherein the first end and the second end of the column are irregular in shape.

19. The solar cell device structure of claim 1 wherein the each of the single crystal structure allows for a diode device region.

20. The solar cell device structure of claim 1 wherein the column provides a grain boundary region for each of the plurality of the single crystal structures.

21. The solar cell device structure of claim 1 wherein the solar cell device has a conversion efficiency ranging from about 10% to 20%.
